(19) United States
(12) Patent Application Publication
(10) Pub. No.: US 2025/0040449 A1
(43) Pub. Date: Jan. 30, 2025

(54) Superconducting device

(71) Applicant: Teknologian tutkimuskeskus VTT Oy, Espoo (FI)

(72) Inventors: Janne Lehtinen, Espoo (FI); Joonas Govenius, Espoo (FI); Jukka-Pekka Kaikkonen, Espoo (FI)

(21) Appl. No.: 18/715,140

(22) PCT Filed: Nov. 22, 2022
(86) PCT No.: PCT/FI2022/050779

§ 371 Date: May 31, 2024

(30) Foreign Application Priority Data
Dec. 1, 2021 (FI) 20216232

(51) Int. Cl. H10N 60/01; H10N 60/12; H10N 60/85

(52) U.S. Cl. CPC H10N 60/0912; H10N 60/12; H10N 60/85

(57) ABSTRACT

According to an example aspect of the present invention, there is provided a method of producing electrodes for superconducting components of quantum computers, quantum sensors or quantum communication devices comprising depositing a first layer on a silicon substrate, the first layer being of a first metal, the first metal being a superconductor, depositing a second layer on the first layer, the second layer being of a second metal, the second metal being a superconductor, and plasma etching through the second layer using a mask layer disposed on the second layer to partially expose the first layer.

### FIELD

The present disclosure relates to superconducting devices, such as, for example, superconducting qubits and resonators, and manufacturing them.

### BACKGROUND

In production of high-quality superconducting resonators, qubits and other devices, minimizing the density of defects, so called two-level systems, TLS, is essential for producing high-quality end products with long coherence times. TLS may impair performance at microwave frequencies, for example. The defect density depends on properties of both the bulk substrate and of the material interfaces. High-resistivity silicon is a substrate alternative that is compatible with tools and processing techniques of the semiconductor industry and does not limit performance in state-of-the-art superconducting qubit devices. Rather, state-of-the-art superconducting qubits are typically limited by defects located at material interfaces. One important interface is the surface of the substrate that is exposed after etching the first metal layer deposited on the substrate. In plasma etching in particular, typical etching methods damage the silicon surface to an extent which affects qubit performance, due to TLS in the damaged regions of the substrate surface.

In known manufacturing processes, plasma etching has been avoided to reduce the density of defects on the substrate surface, or plasma etching is used only in non-critical areas of the device.

### SUMMARY

According to some aspects, there is provided the subject-matter of the independent claims. Some embodiments are defined in the dependent claims.

According to a first aspect of the present disclosure, there is provided a method of producing electrodes for superconducting components of quantum computers, quantum sensors or quantum communication devices comprising depositing a first layer on a silicon substrate, the first layer being of a first metal, the first metal being a superconductor, depositing a second layer on the first layer, the second layer being of a second metal, the second metal being a superconductor, and plasma etching through the second layer using a mask layer disposed on the second layer to partially expose the first layer.

According to a second aspect of the present disclosure, there is provided a method of producing electrodes for superconducting components of quantum computers, quantum sensors or quantum communication devices comprising providing a dielectric layer comprised of a dielectric substance on a silicon substrate, patterning the dielectric layer using wet etching, depositing a metal layer on the silicon substrate, leaving the patterned dielectric layer between the metal layer and the silicon substrate, and plasma etching through the metal layer using a mask layer disposed on the metal layer to at least partially expose the dielectric layer.

According to a third aspect of the present disclosure, there is provided a method of producing electrodes for superconducting components of quantum computers, quantum sensors or quantum communication devices comprising providing a dielectric layer comprised of a dielectric substance on a silicon substrate, patterning the dielectric layer using wet etching, depositing a metal layer on the silicon substrate, leaving the patterned dielectric layer between the metal layer and the silicon substrate, the metal being a superconductor, and planarizing the metal layer using chemical-mechanical polishing to obtain a planar metal layer with openings filled with the dielectric substance.

### BRIEF DESCRIPTION OF THE DRAWINGS

FIGS. 1A-1E illustrate a first method in accordance with at least some embodiments of the present invention;

FIGS. 2A-2E illustrate a second method in accordance with at least some embodiments of the present invention;

FIGS. 3A-3C illustrate a third method in accordance with at least some embodiments of the present invention;

FIG. 4 is a flow graph of the first method in accordance with at least some embodiments of the present invention;

FIG. 5 is a flow graph of the second method in accordance with at least some embodiments of the present invention, and

FIG. 6 is a flow graph of the third method in accordance with at least some embodiments of the present invention.

### EMBODIMENTS

Methods disclosed herein address the problem of plasma etching of metal films damaging a surface of a high-resistivity silicon, Si, substrate. For state-of-the-art superconducting resonators and qubits, a dominant energy loss and decoherence mechanism is believed to be due to defects or residues at the interfaces between various materials. As such, it is desirable that etched surfaces remain smooth and that the thickness of all interface layers, such as native oxides, is minimized. A technical effect of the disclosed methods may be seen, for example, in the fact that a superconducting metal film deposited on a silicon substrate may be etched with high selectivity against the silicon substrate. The employed silicon substrate may comprise a high-resistivity silicon substrate, for example, which is a high-purity silicon substrate characterized by a high resistivity that may be at least 5 kOhm cm, 10 kOhm cm or 20 kOhm cm, for example. An alternative to the methods presented here is to use a sapphire substrate, which acts as a good etch stop for many plasma etch recipes. Nevertheless, the physical ion milling effect associated with plasma etching may still damage the surface. Furthermore, sapphire substrates are less compatible with integrated circuit technologies established in the semiconductor industry, wherefore using a silicon substrate yields a broader range of possible applications. In contrast, the methods disclosed herein are well scalable and may be used for wafer-scale quantum circuits on silicon substrates. In at least some of the disclosed methods, an etch stop is deployed to protect the high-resistivity silicon surface from damage during plasma etching. As will be disclosed herein in more detail, the etch stop may comprise another superconducting metal layer, or a dielectric etch stop. In some embodiments, the etch stop layer may provide the additional benefit of acting as a seed layer for the main superconducting metal film layer, which may be beneficial if the desired crystal phase of the superconducting metal layer does not naturally grow directly on silicon. The seed layer may also act as a diffusion barrier between the silicon substrate and the metal layer, preventing the formation of, for example, silicides. This is particularly beneficial in applications where the produced structures are exposed to elevated temperatures in subsequent processing steps.

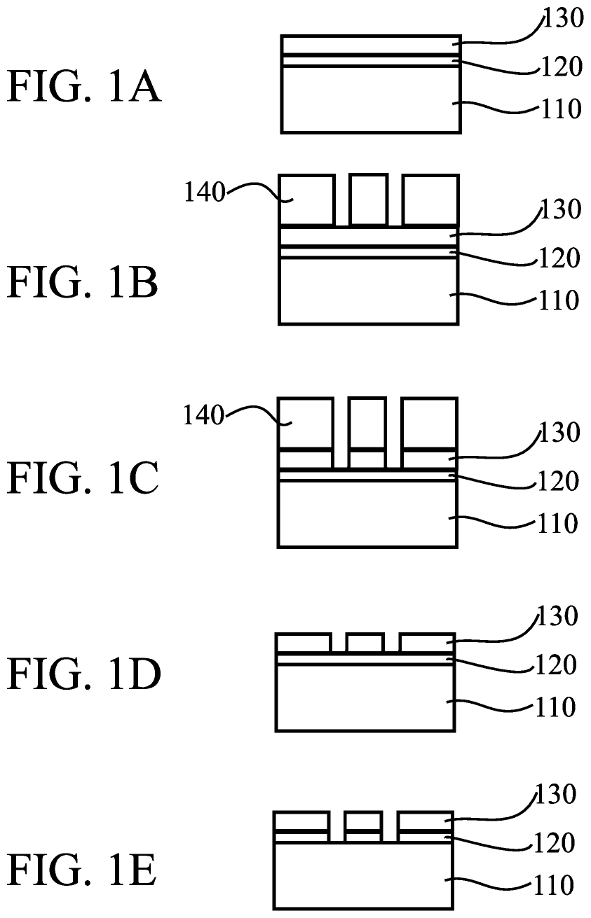

FIGS. 1A-1E illustrate a first method in accordance with at least some embodiments of the present invention. The figures are not drawn to scale. In the first method, a superconducting metal, such as aluminum or titanium nitride, TiNₓ, is used as an etch stop layer to protect the high-resistivity silicon layer from plasma etching. For TiNₓ, the nitrogen concentration, x, may be chosen such that the superconducting transition temperature of the TiNₓ film exceeds 0.5 K. Aluminum, Al, is one of the few known superconductors which have been used to make high-quality resonators and that has proven to be a good BCS-type superconductor. Aluminum is nearly inert to sulphur hexafluoride, SF6, based plasma etching chemistry, which makes it an ideal etch stop layer for etching metals such as niobium and tantalum, Ta, for example. This enables controllable etching of the metal layer, such as a niobium or tantalum layer, even when the etch stop layer is very thin. For example, the etch stop layer may be between 2 and 40 nanometers thick. As a more specific example, the etch stop layer may be between 4 and 20 nanometers thick. The thinness of the etch stop layer provides the benefit that, due to the superconducting proximity effect, superconductivity will be induced in the thin etch stop layer from the thicker metal layer on top of it, such that both films will superconduct at temperatures that are low compared to the transition temperature of the thick superconducting metal film on top. For example, a thin 10 nm layer of Al is affected by an adjacent 200 nm layer of niobium, Nb, such that the bilayer will behave similarly to a single 210 nm layer of Nb at temperatures well below the critical temperature of Nb. Aluminum may, furthermore, be removed without damaging unmasked niobium, tantalum or silicon structures using wet etching, for example. In this patent application, wet etching is to be understood to include chemical etching in liquid etchants as well as chemical etching in gas phase etchants, such as vapor-phase acids or bases. For these reasons, beneficially, a thin aluminum layer that remains between the high-resistivity silicon substrate and a separate metal layer will not negatively impact the performance of the eventual constructed device.

Superconducting titanium nitride is an attractive alternative etch stop layer for at least two reasons. First, a thin layer of titanium nitride, for example 10 nm, is a good diffusion barrier that prevents mixing of Nb or Ta with Si even at elevated temperatures, for example at 400 C. The same titanium nitride layer is also a suitable seed layer for sputtering mostly α-phase Ta at room temperature, which may not be possible directly on Si. Tantalum that is mostly in its α-phase, as characterized by a low resistivity below approximately 30 μOhm cm, is one of the most promising materials for superconducting qubits while β-phase Ta, which naturally grows on Si, is not presently known to be suitable for superconducting transmon-type qubits. Titanium nitride is not as inert as aluminum in some common plasma etch chemistries, but sufficient selectivity in etching Nb or Ta against titanium nitride is achievable with modern etch tools, such that the plasma etch can be stopped after the Nb or Ta film has been etched through but before the titanium nitride film is fully etched. For example, plasma etch chemistry based on sulfur hexafluoride, SF6, may be used. The remaining titanium nitride can be wet etched with high selectivity against Si and Ta.

In FIG. 1A, a high-resistivity silicon substrate 110 is provided with an etch stop layer 120 of a superconductor, such as aluminum or titanium nitride. Etch stop layer 120 may be provided onto substrate 110 by deposition, for example. The thickness of etch stop layer 120 may be between 2 and 40 nm, for example. In particular, the thickness may be 2 nm, 4 nm, 10 nm or 40 nm, with an accuracy of +/−0.5 nm. A metal layer 130 that is typically thicker, for example 200 nm of Ta, is deposited on etch stop layer 120 to obtain the two-layered structure deposited on a silicon substrate, illustrated in FIG. 1A.

Moving to FIG. 1B, a mask layer 140 is provided on metal layer 130. The mask may comprise a suitable polymer material, for example. The mask is patterned with a shape denoting the shape of an eventual device, or part thereof, that is to be constructed. Other masking strategies, such as a hard mask consisting of patterned silicon oxide, can alternatively be used as mask layer 140. Such a silicon oxide mask may be grown, for example, by plasma-enhanced chemical vapor deposition, PECVD. The hard mask may also comprise other materials, such as sputtered aluminum or aluminum oxide grown by atomic layer deposition, ALD. In general, etch stop layer 120 may be seen as a first layer, and metal layer 130 as a second layer.

Proceeding to FIG. 1C, plasma etching is conducted, for example using SF6, to shape metal layer 130 in accordance with the pattern of mask layer 140. Sufficient selectivity of the plasma etch against etch stop layer 120 stops the etch from reaching the underlying high-resistivity silicon substrate 110. The plasma etching only partially etches etch stop layer 120 in the unmasked regions. In other words, the plasma etching stops at or in the etch stop layer 120 in the unmasked regions. In yet further words, the plasma etching does not penetrate etch stop layer 120.

Advancing to FIG. 1D, mask layer 140 is removed. In the case of a standard positive photoresist, this removal can be done using a standard positive photoresist remover, such as EKC830 PosiStrip. In the case of a hard mask consisting of silicon oxide, aluminum or aluminum oxide, dilute hydrofluoric acid may be used for the mask removal. The removal of mask layer 140 may also be delayed until after etch stop layer 120 has been wet etched, or etch stop layer 120 and mask layer 140 may be removed in the same step if they are etched in the same chemical. This protects metal layer 130 in case the wet etch used to remove etch stop layer 120 also etches metal layer 130.

Finally progressing to FIG. 1E, the remainder of the partially etched etch stop layer 120 is removed using a wet etch, for example. Other manufacturing phases may be performed before the wet etching of the etch stop layer, such that the protective remaining part of etch stop layer 120 may be removed among the last phases of manufacture, to expose silicon surface 110 only after such additional phases of manufacture have been completed, as such additional phases could damage the silicon surface of substrate 110. The resulting, newly-exposed part of high-resistivity silicon 110 has a highly planar and smooth surface in case, for example, standard clean 1, SC-1, (mixture of water, ammonia and hydrogen peroxide) heated to about 60 C is used to remove a titanium nitride etch stop layer or dilute hydrofluoric acid, buffered hydrofluoric acid, mixture of phosphoric and nitric acid, or dilute tetramethylammoniumhydroxide, TMAH, is used to remove an Al etch stop layer. The wet etch used to remove etch stop layer 120 may also effectively clean the surface of high-resistivity silicon substrate 110, such as in the case of SC-1 or in the case of dilute hydrofluoric acid. After removing etch stop layer 120, additional processing steps may be performed to remove and passivate oxides on exposed surfaces, for example using dilute hydrofluoric acid. Etch stop layer 120 remaining between the high-resistivity silicon substrate 110 and metal layer 130 may be a physical indicator that the first method has been used to manufacture the resulting device. An additional physical indicator may be that the silicon is minimally over-etched in the metal-free region as compared to the metal-covered region, for example by less than 5 nm. These physical indicators may be visible in SEM/TEM images, for example.

In one specific embodiment of the invention etch stop layer 120 comprises titanium nitride and metal layer 130 comprises tantalum. This combination is particularly beneficial since mostly α-phase tantalum can be sputter deposited on titanium nitride, because titanium nitride acts as an effective diffusion barrier between tantalum and the high-resistivity silicon substrate 110, and because titanium nitride can be wet etched with high selectivity against both tantalum and silicon, using SC-1 heated to about 60 C. A diffusion barrier between silicon substrate 110 and metal layer 130 may be provided if metal layer 130 is exposed to elevated temperatures during fabrication of other structures on the same substrate, as tantalum can intermix with silicon, forming tantalum silicide. The same is true for intermixing of niobium and silicon. The additional structures fabricated on the substrate may include, for example, through-silicon vias that create electrical connections between the front and back sides of the silicon substrate, or other vias connecting layers on or within the substrate. High temperatures exceeding, for example, 400 C are often required in fabrication of such structures. For example, atomic layer deposition, ALD, which is well-suited for depositing conformal superconducting films within vias, is challenging at low temperatures for superconducting materials, such as titanium nitride. A bilayer where etch stop layer 120 consists of titanium nitride and metal layer 130 consists of, for example, tantalum or niobium is therefore beneficial when fabrication of vias is required on the same substrate, even if etch stop layer 120 is etched with conventional plasma etching methods.

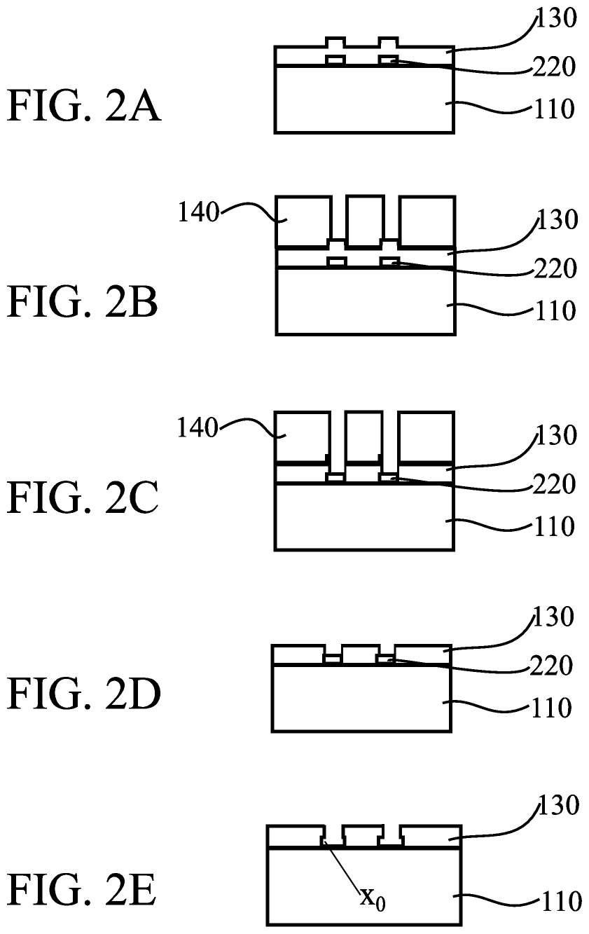

FIGS. 2A-2E illustrate a second method in accordance with at least some embodiments of the present invention. The figures are not drawn to scale. In the second method, a dielectric is deposited or grown on the high-resistivity silicon substrate using a method that leaves a smooth high-quality interface between the silicon substrate and the generated dielectric layer. For example, a silicon oxide layer may be grown by thermal oxidization, a silicon oxide layer may be deposited using PECVD, or an aluminum oxide layer may be deposited using ALD. The dielectric may be patterned using, for example, wet etching that is highly selective against silicon. Such wet etchant may comprise hydrofluoric acid, HF, or buffered HF, BHF, for example. Then a metal layer, for example niobium or tantalum, is deposited on the patterned dielectric layer. The pattern of the dielectric layer is chosen such that the dielectric layer functions as a spatially defined sacrificial protection layer of the silicon substrate during plasma etching of the metal layer. That is, the metal layer may then be etched using plasma etching methods with a slightly undersized opening in a mask, such as polymer mask, as compared to the patterned sacrificial layer. In other words, the dielectric layer and the mask layer may be patterned according to features of a same structure, with the features being slightly larger in the dielectric layer. The appropriate difference in the feature size is determined by the alignment accuracy and line width reproducibility of the lithography and etch processes used. For example, feature width may be 10 nm, 50 nm, or 100 nm larger, in a given direction, in the dielectric layer than in the mask openings for metal etching. Optionally, unevenness of the metal layer, caused by the underlying dielectric, may be removed before or after plasma etching using chemical-mechanical polishing, CMP, for example. The residual dielectric material may be removed using wet etching, revealing a smooth, high-quality silicon substrate surface undamaged by the plasma etching process. This final wet etchant may comprise diluted TMAH or HF, for example.

In FIG. 2A, a dielectric layer 220 is obtained on a high-resistivity silicon substrate 110. The dielectric layer may be obtained thereon by deposition that does not damage the silicon surface, for example PECVD or ALD, or by growth that creates a new high-quality interface between the generated dielectric and the bulk of the substrate, for example thermal oxidization. Examples of suitable dielectrics for the second and third methods include silicon oxide SiO₂, aluminum oxide Al₂O₃ and silicon nitride, SiNₓ. Dielectric layer 220 is patterned using wet etching that is highly selective against silicon, for example, HF or BHF may be used in such wet etching. The patterning of dielectric layer 220 determines the shape of resulting structures in this part of the device to be manufactured. A metal layer 130, for example niobium or tantalum, is deposited on dielectric layer 220, leaving the patterned dielectric layer 220 between the high-resistivity silicon substrate 110 and metal layer 130. Metal layer 130 may have an uneven surface due to the presence of the patterned dielectric layer 220 underneath, as illustrated in FIG. 2A. In general, dielectric layer 220 may be seen as a first layer, and metal layer 130 as a second layer.

Moving on to FIG. 2B, a mask layer 140 is provided onto metal layer 130. The mask is patterned with a pattern reflecting the pattern of the underlying dielectric layer 220, in detail, mask layer 140 may have grooves at places corresponding to the presence of dielectric 220 underneath, the grooves being smaller in cross-sectional area in the plane of substrate 110 than the underlying dielectric 220. The shape of structures of the resulting device to be manufactured are defined in both the patterning of the dielectric layer 220 and the patterning of mask layer 140.

Proceeding to FIG. 2C, plasma etching is performed through mask layer 140, removing the part(s) of metal layer 130 left exposed by mask layer 140. The plasma etch stops within dielectric layer 220 and does not affect high-resistivity silicon substrate 110. Dielectric layer 220 may be partially etched during this plasma etch step.

Advancing to FIG. 2D, mask layer 140 is removed using standard polymer mask removal methods. A planarization process may be optionally employed to even out any residual unevenness of metal layer 130 caused by the underlying dielectric layer 220. Such planarization may also be performed already after deposition of metal layer 130.

Progressing then to FIG. 2E, the remaining dielectric layer 220 is removed using a wet etch, for example based on TMAH or HF. In case the dielectric layer is patterned to have larger features than the corresponding features of mask layer 140, recesses x₀ are formed at the interface between the high-resistivity silicon substrate 110 and metal layer 130. The thickness of the recesses may be selected by selection of the corresponding thickness of dielectric layer 220. The minimum thickness of dielectric layer 220 is determined by the reproducibility of the plasma etch step of metal layer 130 and the selectivity of that etch method against layer 130 in comparison to layer 220. The dielectric layer may, for example, have a thickness of 2 nm, 5 nm, 20 nm or 50 nm. The thickness of metal layer 130 is typically larger and may be 20 nm, 100 nm or 500 nm, for example. In case of aluminum oxide etch stop layer and a thick niobium superconducting metal layer, the thickness of etch stop layer 220 may be, for example, only 1% or 10% of the thickness of the superconducting metal layer. In case of silicon oxide etch stop layer, etch stop layer 220 may be, for example, 10% or 40% of the thickness of metal layer 130, since silicon oxide etches more easily than aluminum oxide in several common recipes for plasma etching of metals. There may be further manufacturing phases between the plasma etch of metal layer 130 and removal of the protective dielectric layer 220. The final wet etch to remove the dielectric layer may also function as a highly efficient surface cleaning and passivation step, for example in case dilute HF is used as the final wet etch. Recesses x₀ and minimal silicon overetching similar to the first method may be physical indicators that the second method has been used to manufacture the resulting device.

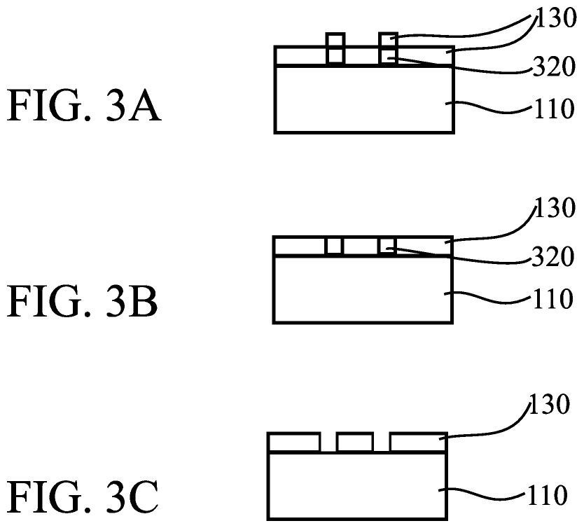

FIGS. 3A-3C illustrate a third method in accordance with at least some embodiments of the present invention. The figures are not drawn to scale. In the third method a patterned dielectric is used as in the second method, however instead of plasma etching, CMP is employed to create openings in the metal layer. In the third method, the dielectric is provided in the same thickness as, or thicker than, the desired metal layer thickness in the final device. The desired metal film may be, for example, a 20 nm, 100 nm or 500 nm thick niobium or tantalum layer. The underlying patterned dielectric causes unevenness in the metal layer, which is removed by CMP in a process known as planarization. Enough metal is removed using CMP such that openings in the metal layer are created. A wet etch is employed using, for example, dilute TMAH or HF, to remove the dielectric exposed by the CMP phase.

In FIG. 3A, a high-resistivity silicon substrate 110 is provided with a dielectric layer 320, which comprises a dielectric substance, such as SiO₂, AlO₃ or SiNₓ, for example. The dielectric layer in the third method is of the same thickness, or thicker, than the eventual metal layer on silicon substrate 110. The dielectric layer may be patterned as in the second method with a pattern defining the shape of a structure to be constructed. Metal layer 130 is deposited on the high-resistivity silicon substrate 110, leaving the patterned dielectric layer 320 between substrate 110 and metal layer 130, as illustrated. Metal layer 130 will have a substantially uneven form due to the presence of the patterned dielectric layer 320 underneath it, the dielectric having at least the same thickness as metal layer 130 will have after planarization. The metal layer may comprise a niobium layer or a tantalum layer, for example.

As seen in the figure, the underlying dielectric layer causes protrusions in metal layer 130 corresponding to locations where dielectric layer 320 remains.

Proceeding to FIG. 3B, a planarization process, for example CMP, is performed to remove the uneven protrusions of metal layer 130 caused by the underlying dielectric layer 320. Even after protrusions have been planarized, the polishing process may be continued until metal layer 130 is of the desired thickness. Following this, metal layer 130 has grooves filled with the dielectric substance of the patterned dielectric layer 320. The pattern of openings in metal layer 130 may be chosen specifically such that the planarization process succeeds, for example by adding openings that serve no other functional purpose than improving the uniformity of the planarization step. This may be beneficial, as planarization may not succeed optimally in case the openings are very sparse, for example.

Finally arriving at the device illustrated in FIG. 3C, wet etching, for example based on TMAH or HF, is used to remove the dielectric substance of dielectric layer 320. In particular, the dielectric substance is thereby removed from the grooves. There may be further manufacturing phases between the planarization of metal layer 130 and removal of dielectric layer 320 from the grooves. As a result of this manufacturing method, the negative sidewall profile of the grooves in metal layer 130 may be characteristic of the positive sidewall of the wet-etched dielectric substance of layer 320 present during manufacture. This sidewall characteristic and minimal silicon over-etching similar to the first method may be physical indicators that the third method has been used in manufacture of the device.

Overall, using the first, second and/or third method, a device may be beneficially manufactured, wherein the device may comprise, for example, a superconducting transmission line, such as a co-planar waveguide, or an electrode of a superconducting qubit, such as a transmon.

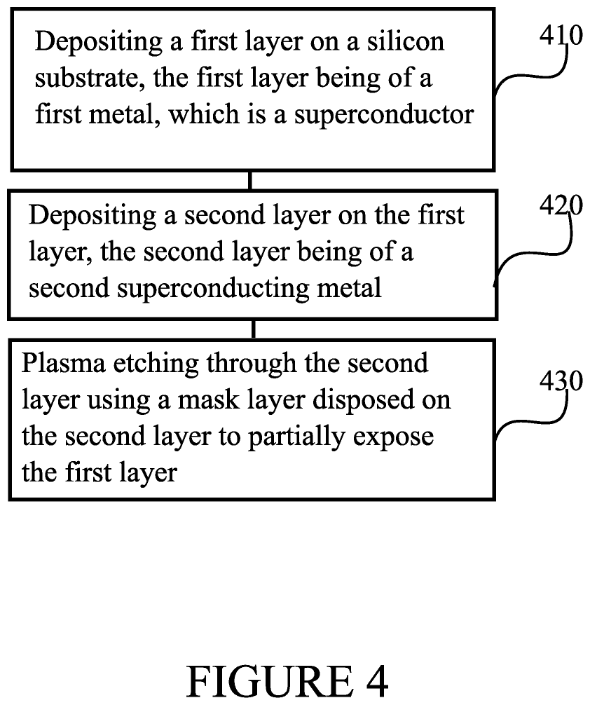

FIG. 4 is a flow graph of the first method in accordance with at least some embodiments of the present invention. The method is a method of producing electrodes for superconducting components of quantum computers, quantum sensors or quantum communication devices, such as superconducting quantum bits, superconducting resonators, or superconducting transmission lines

Phase 410 comprises depositing a first layer on a silicon substrate, the first layer being of a first metal, the first metal being a superconductor. Phase 420 comprises depositing a second layer on the first layer, the second layer being of a second superconducting metal different from the first metal. Phase 430 comprises plasma etching through the second layer using a mask layer disposed on the second layer to partially expose the first layer. A further phase 440 may comprise wet etching of the partially exposed first layer.

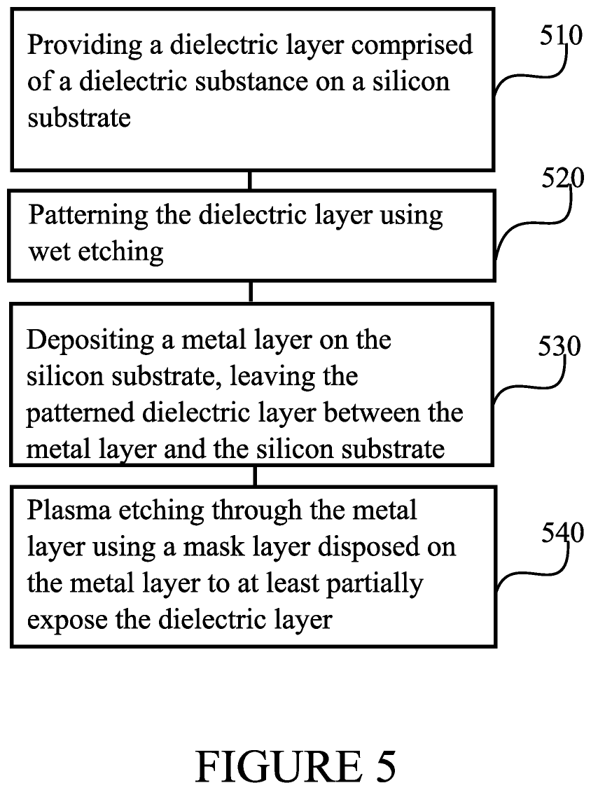

FIG. 5 is a flow graph of the second method in accordance with at least some embodiments of the present invention.

Phase 510 comprises providing a dielectric layer comprised of a dielectric substance on a silicon substrate. Phase 520 comprises patterning the dielectric layer using wet etching. In phase 520, an etch rate difference larger than 1:100 between silicon and the dielectric layer may apply. Phase 530 comprises depositing a metal layer on the silicon substrate, leaving the patterned dielectric layer between the metal layer and the silicon substrate. Phase 540 comprises plasma etching through the metal layer using a mask layer disposed on the metal layer to at least partially expose the dielectric layer. The mask layer may be lithographically defined. A further phase 550 may comprise wet etching of the partially exposed dielectric layer.

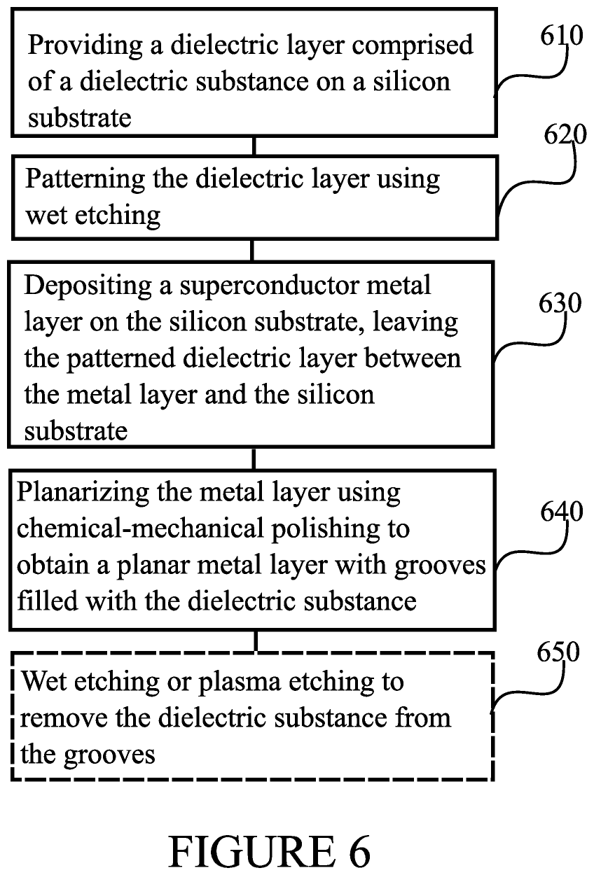

FIG. 6 is a flow graph of the third method in accordance with at least some embodiments of the present invention.

Phase 610 comprises providing a dielectric layer comprised of a dielectric substance on a silicon substrate. Phase 620 comprises patterning the dielectric layer using wet etching. Phase 630 comprises depositing a metal layer on the silicon substrate, leaving the patterned dielectric layer between the metal layer and the silicon substrate, the metal being a superconductor. Phase 640 comprises planarizing the metal layer using chemical-mechanical polishing to obtain a planar metal layer with openings filled with the dielectric substance. Finally, phase 650 comprises wet etching to remove the dielectric substance from the grooves.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

### INDUSTRIAL APPLICABILITY

At least some embodiments of the present invention find industrial application in manufacture of electrical components, such as superconducting qubits.

### Acronyms List

ALD atomic layer deposition
BCS Bardeen-Cooper-Schrieffer
BHF buffered HF
CMP chemical-mechanical polishing
HF hydrofluoric acid
PECVD plasma enhanced chemical vapor deposition
SC-1 standard clean 1
SEM scanning electron microscope
SF6 sulphur hexafluoride
TEM transmission electron microscope
TLS two-level systems
TMAH tetramethylammonium hydroxide

REFERENCE SIGNS LIST

| | |
|---|---|
| 110 | silicon substrate |
| 120 | etch stop layer |
| 130 | metal layer |
| 140 | mask layer |
| 220, 320 | dielectric layer |
| 410-430 | phases of the method (first method) of FIG. 4 |
| 510-540 | phases of the method (second method) of FIG. 5 |
| 610-650 | phases of the method (third method) of FIG. 5 |

1. A method of producing electrodes for superconducting components of quantum computers, quantum sensors or quantum communication devices comprising:
depositing a first layer on a silicon substrate, the first layer being of a first metal, the first metal being a superconductor;
depositing a second layer on the first layer, the second layer being of a second metal, the second metal being a superconductor, and
plasma etching through the second layer using a mask layer disposed on the second layer to partially expose the first layer, wherein the silicon substrate comprises high resistivity silicon, and the plasma etching using the mask layer does not penetrate the first layer.

2. The method according to claim 1, wherein the first metal comprises aluminum or titanium nitride.

3. The method according to claim 1, wherein the second metal comprises niobium or tantalum.

4. The method according to claim 3, wherein the first metal comprises titanium nitride and wherein the second metal comprises tantalum.

5. The method according to claim 1, wherein the first metal comprises titanium nitride and wherein vias are fabricated on the silicon substrate.

6. The method according to claim 1, further comprising removing the mask layer.

7. The method according to claim 1, further comprising removing the exposed part of the first layer using wet etching.

8. The method according to claim 1, further comprising removing the exposed part of the first layer using plasma etching.

9. The method according to claim 1, wherein the first layer has a thickness between 2 and 40 nanometers.

10. A method of producing electrodes for superconducting components of quantum computers, quantum sensors or quantum communication devices comprising:
providing a dielectric layer comprised of a dielectric substance on a silicon substrate;
patterning the dielectric layer using wet etching;
depositing a metal layer on the silicon substrate, leaving the patterned dielectric layer between the metal layer and the silicon substrate, and
plasma etching through the metal layer using a mask layer disposed on the metal layer to at least partially expose the dielectric layer, wherein the silicon substrate comprises high resistivity silicon.

11. The method according to claim 10, further comprising wet etching to remove the dielectric layer to partially expose the silicon substrate.

12. The method according to claim 10, wherein the metal layer is a niobium layer or a tantalum layer.

13. The method according to claim 10, further comprising removing the mask layer.

14. The method according to claim 13, further comprising chemical-mechanical polishing the metal layer after the removal of the mask layer or after depositing the metal layer.

15. A method of producing electrodes for superconducting components of quantum computers, quantum sensors or quantum communication devices comprising:
providing a dielectric layer comprised of a dielectric substance on a silicon substrate;
patterning the dielectric layer using wet etching;
depositing a metal layer on the silicon substrate, leaving the patterned dielectric layer between the metal layer and the silicon substrate, the metal being a superconductor, and
planarizing the metal layer using chemical-mechanical polishing to obtain a planar metal layer with openings filled with the dielectric substance, wherein the silicon substrate comprises high resistivity silicon.

16. The method according to claim 15, further comprising wet etching the dielectric layer in the openings in the metal layer to partially expose the silicon substrate.

17. The method according to claim 15, wherein the dielectric substance comprises silicon oxide, aluminum oxide or silicon nitride.

18. The method according to claim 15, wherein the metal layer is a niobium layer or a tantalum layer.

19. The method according to claim 18, wherein the method is a method of manufacturing electrodes for superconducting qubits, superconducting resonators, or superconducting transmission lines.
